(19) United States
(12) Patent Application Publication
(10) Pub. No.: US 2026/0006953 A1
(43) Pub. Date: Jan. 1, 2026

(54) LIGHT-EMITTING DEVICE AND METHOD FOR MANUFACTURING LIGHT-EMITTING DEVICE

(71) Applicant: NICHIA CORPORATION, Anan-shi (JP)

(72) Inventors: Takayuki IGARASHI, Yokohama-shi (JP); Yoshifumi HODONO, Yokohama-shi (JP)

(73) Assignee: NICHIA CORPORATION, Anan-shi (JP)

(21) Appl. No.: 19/250,231

(22) Filed: Jun. 26, 2025

(30) Foreign Application Priority Data
Jun. 27, 2024 (JP) 2024-104243

(51) Int. Cl. H10H 20/851; H10H 20/01; H10H 20/856

(52) U.S. Cl. CPC H10H 20/8514; H10H 20/0361; H10H 20/0363; H10H 20/856

(57) ABSTRACT

A light-emitting device includes a light-emitting element and a light-transmissive member disposed on the light-emitting element. The light-emitting element has a first upper surface, a first lower surface, and at least one first lateral surface connecting the first upper surface and the first lower surface. The light-transmissive member has a second upper surface, a second lower surface, and at least one second lateral surface connecting the second upper surface and the second lower surface. The at least one second lateral surface includes a first region inclined toward a center of the second lower surface as the first region extends downward. The first region is a flat or curved surface. In a top view, an outer peripheral end of each second lateral surface overlaps an outer peripheral end of each first lateral surface, and an outer peripheral end of the second lower surface overlaps a lower end of the first region.

### CROSS REFERENCE TO RELATED APPLICATION

This application claims priority to Japanese Patent Applications No. 2024-104243, filed on Jun. 27, 2024, the entire contents of which are hereby incorporated by reference.

### BACKGROUND

### Technical Field

An embodiment relates to a light-emitting device and a method for manufacturing the light-emitting device.

### Background Art

A light-emitting device including a light-transmissive member disposed on a light-emitting element is known (for example, see Japanese Patent Publication No. 2020-188180). In such a light-emitting device, there is a demand for increase in luminance.

### SUMMARY

One object of certain embodiments is to provide a light-emitting device that can enhance luminance and a method for manufacturing the light-emitting device.

A light-emitting device according to an embodiment of the present invention includes a light-emitting element, and a light-transmissive member disposed on the light-emitting element. The light-emitting element has a first upper surface, a first lower surface, and at least one first lateral surface connecting the first upper surface and the first lower surface. The light-transmissive member has a second upper surface, a second lower surface, and at least one second lateral surface connecting the second upper surface and the second lower surface. The at least one second lateral surface includes a first region inclined toward a center of the second lower surface as the first region extends downward. The first region is a flat surface or a curved surface. In a top view, an outer peripheral end of each of the at least one second lateral surface overlaps an outer peripheral end of each of the at least one first lateral surface. In the top view, an outer peripheral end of the second lower surface overlaps a lower end of the first region.

A method for manufacturing a light-emitting device according to an embodiment of the present invention includes: providing a wafer and a light-transmissive substrate, the wafer including a plurality of light-emitting elements and having a first main surface and a first rear surface, the light-transmissive substrate having a second main surface and a second rear surface provided with a slit;
bonding the second rear surface of the light-transmissive substrate to the first main surface of the wafer to form a structure in which the light-transmissive substrate is bonded to the wafer; and collectively singulating the wafer and the light-transmissive substrate into individual structures by dividing the structure at a position overlapping the slit. In the step of providing, the light-transmissive substrate provided with the slit having an inclined surface inclined widening from the second main surface toward the second rear surface is provided. The inclined surface is a flat surface or a curved surface. In the step of singulating, the structure is divided such that a part of the slit remains in the light-transmissive substrate of one of the individual structures.

### BRIEF DESCRIPTION OF DRAWINGS

FIG. 1 is a schematic plan view illustrating a light-emitting device according to a first embodiment.

FIG. 2 is a schematic cross-sectional view taken along line II-II in FIG. 1.

FIG. 3 is a schematic enlarged view of a region R1 illustrated in FIG. 2.

FIG. 4 is a schematic cross-sectional view illustrating a part of a light-emitting device according to a first modified example of the first embodiment.

FIG. 5 is a schematic cross-sectional view illustrating a part of a light-emitting device according to a second modified example of the first embodiment.

FIG. 6 is a schematic cross-sectional view illustrating a part of a light-emitting device according to a third modified example of the first embodiment.

FIG. 7 is a schematic cross-sectional view illustrating light emission in a light-emitting device in the related art.

FIG. 8 is a schematic cross-sectional view illustrating light emission in the light-emitting device according to the first embodiment.

FIG. 9 is a schematic plan view illustrating a light-emitting device according to a second embodiment.

FIG. 10 is a schematic cross-sectional view illustrating the light-emitting device according to the second embodiment.

FIG. 11 is a schematic plan view illustrating a light-emitting device according to a third embodiment.

FIG. 12 is a schematic cross-sectional view illustrating the light-emitting device according to the third embodiment.

FIG. 13 is a schematic plan view illustrating a light-emitting device according to a fourth embodiment.

FIG. 14 is a schematic cross-sectional view illustrating the light-emitting device according to the fourth embodiment.

FIG. 15 is a schematic plan view illustrating a light-emitting device according to a fifth embodiment.

FIG. 16 is a schematic cross-sectional view illustrating the light-emitting device according to the fifth embodiment.

FIG. 17 is a schematic plan view illustrating a light-emitting device according to a sixth embodiment.

FIG. 18 is a schematic cross-sectional view illustrating the light-emitting device according to the sixth embodiment.

FIG. 19 is a schematic cross-sectional view illustrating a first step of a method for manufacturing the light-emitting device according to the first embodiment.

FIG. 20 is a schematic cross-sectional view illustrating a second step of the method for manufacturing the light-emitting device according to the first embodiment.

FIG. 21 is a schematic cross-sectional view illustrating the second step of the method for manufacturing the light-emitting device according to the first embodiment.

FIG. 22 is a schematic cross-sectional view illustrating the second step of the method for manufacturing the light-emitting device according to the first embodiment.

FIG. 23 is a schematic cross-sectional view illustrating the second step of the method for manufacturing the light-emitting device according to the first embodiment.

FIG. 24 is a schematic cross-sectional view illustrating a third step of the method for manufacturing the light-emitting device according to the first embodiment.

FIG. 25 is a schematic cross-sectional view illustrating the third step of the method for manufacturing the light-emitting device according to the first embodiment.

FIG. 26 is a schematic cross-sectional view illustrating a fourth step of the method for manufacturing the light-emitting device according to the first embodiment.

FIG. 27 is a schematic cross-sectional view illustrating a fifth step of the method for manufacturing the light-emitting device according to the first embodiment.

FIG. 28 is a schematic cross-sectional view illustrating a sixth step of the method for manufacturing the light-emitting device according to the first embodiment.

FIG. 29 is a schematic cross-sectional view illustrating the sixth step of the method for manufacturing the light-emitting device according to the first embodiment.

FIG. 30 is a schematic plan view illustrating a light-transmissive substrate in the method for manufacturing the light-emitting device according to the first embodiment.

FIG. 31 is a schematic perspective view illustrating the light-transmissive substrate in the method for manufacturing the light-emitting device according to the first embodiment.

FIG. 32 is a schematic perspective view illustrating a part of the light-transmissive substrate in the method for manufacturing the light-emitting device according to the first embodiment.

FIG. 33 is a schematic plan view illustrating a light-transmissive substrate in a method for manufacturing the light-emitting device according to the second embodiment.

FIG. 34 is a schematic plan view illustrating a light-transmissive substrate in a method for manufacturing the light-emitting device according to the third embodiment.

FIG. 35 is a schematic plan view illustrating a light-transmissive substrate in a method for manufacturing the light-emitting device according to the fourth embodiment.

FIG. 36 is a schematic plan view illustrating a light-transmissive substrate in a method for manufacturing the light-emitting device according to the fifth embodiment.

FIG. 37 is a schematic plan view illustrating a light-transmissive substrate in a method for manufacturing the light-emitting device according to the sixth embodiment.

### DETAILED DESCRIPTION

Embodiments of the present invention are described below with reference to the drawings. The drawings are schematic or conceptual, and the relationships between the thicknesses and the widths of portions, the ratios of sizes between portions, and the like are not necessarily the same as the actual values thereof. The dimensions and the proportions may be illustrated differently between the drawings, even in a case in which the same portion is illustrated.

In the present specification and the drawings, the same elements as those already described are denoted by the same reference characters, and detailed description thereof is omitted as appropriate.

For clarity of explanation, the arrangements and structures of portions are described below by using an XYZ orthogonal coordinate system. The X, Y, and Z axes are orthogonal to each other. The direction in which the X-axis extends is referred to as an “X direction,” the direction in which the Y-axis extends is referred to as a “Y direction,” and the direction in which the Z-axis extends is referred to as a “Z direction.” For clarity of explanation, in the Z direction, the direction of an arrow is referred to as an “upward direction” and the direction opposite thereto is referred to as a “downward direction,” but these directions are irrespective of the gravitational direction. In addition, viewing from the upward direction to the downward direction is referred to as “top view.”

### Light-Emitting Device

### First Embodiment

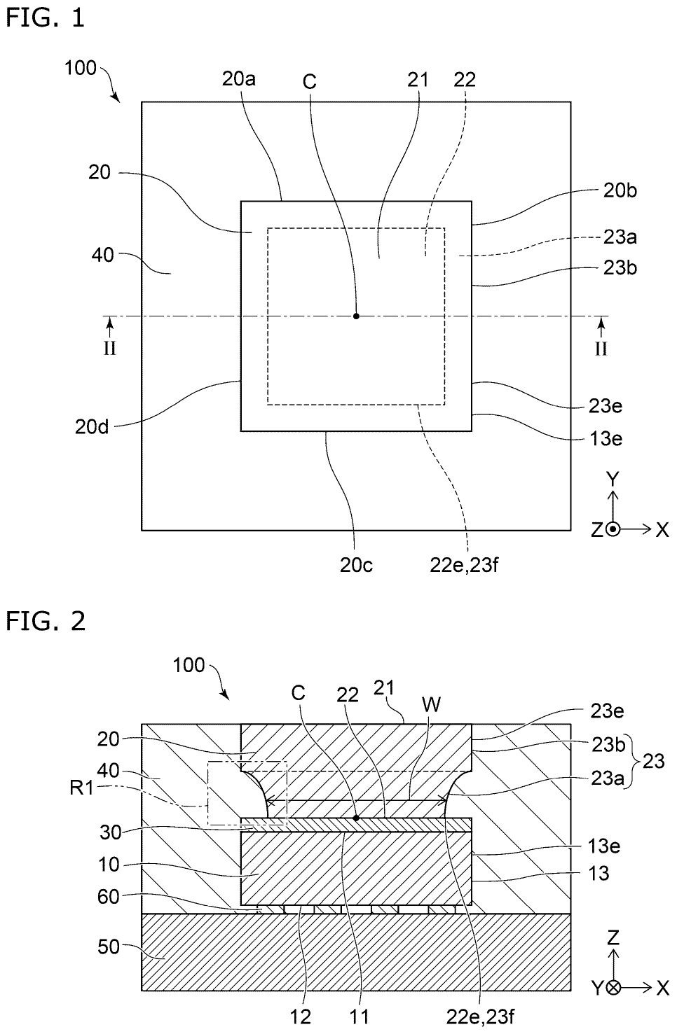

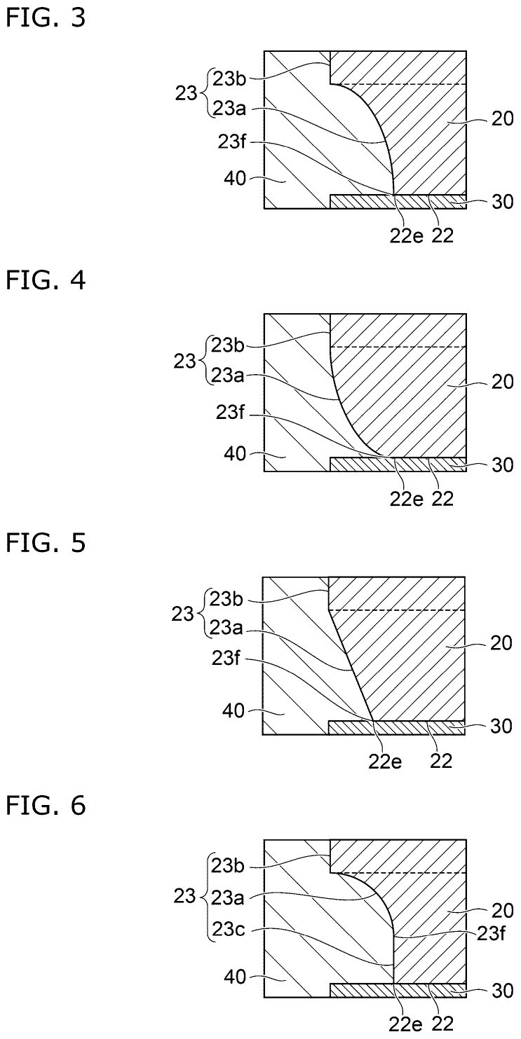

FIG. 1 is a schematic plan view illustrating a light-emitting device according to a first embodiment. FIG. 2 is a schematic cross-sectional view taken along line II-II in FIG. 1. FIG. 3 is a schematic enlarged view of a region R1 illustrated in FIG. 2.

As illustrated in FIGS. 1 to 3, a light-emitting device 100 according to the first embodiment includes a light-emitting element 10 and a light-transmissive member 20. An outer shape of the light-emitting device 100 in top view is a quadrangle. The outer shape of the light-emitting device 100 in top view may be a polygon other than a quadrangle.

The light-emitting element 10 includes a p-type semiconductor layer, an active layer, and an n-type semiconductor layer. Each of the p-type semiconductor layer, the active layer, and the n-type semiconductor layer are each made of, for example, a nitride semiconductor. In the present specification, for example, it is assumed that the “nitride semiconductor” encompasses all semiconductors having compositions represented by a chemical formula of InₓAl_{y}Ga_{1-x-y}N (0≤x≤1, 0≤y≤1, x+y≤1) in which the composition ratios x and y are varied within the respective ranges. Further, the “nitride semiconductor” also encompasses a semiconductor further containing, in the above chemical formula, a group V element other than nitrogen (N), and semiconductors further containing, in the above chemical formula, various elements added to control various physical properties such as a conductivity type.

The n-type semiconductor layer contains, for example, silicon (Si) as an n-type impurity. The p-type semiconductor layer contains, for example, magnesium (Mg) as a p-type impurity. The active layer is a light-emitting layer that emits light and has a multiple quantum well (MQW) structure including a plurality of barrier layers and a plurality of well layers, for example. The active layer may be a single quantum well (SQW) in which one well layer is disposed between two barrier layers.

The p-type semiconductor layer, the active layer, and the n-type semiconductor layer may be a group III-V semiconductor other than a nitride semiconductor. The group III-V semiconductor may be, for example, GaAs, GaAsP, AlGaAs, AlGaInP, or the like. These materials have a mixed crystal composition in the range of a direct transition type semiconductor.

The light-emitting element 10 has a first upper surface 11, a first lower surface 12, and first lateral surfaces 13. The first lateral surfaces 13 connect the first upper surface 11 and the first lower surface 12. In the light-emitting device 100, the first lower surface 12 is a surface parallel to the first upper surface 11. In the light-emitting device 100, the first upper surface 11 and the first lower surface 12 are flat surfaces along an X-Y plane. In the light-emitting device 100, the first lateral surfaces 13 are flat surfaces perpendicular to the first upper surface 11 and the first lower surface 12. In the light-emitting device 100, the first lateral surfaces 13 are flat surfaces extending along the Z direction (that is, an up-down direction).

In the light-emitting device 100, the outer shape of the light-emitting element 10 in top view is a quadrangle. The outer shape of the light-emitting element 10 in top view may be a polygon other than a quadrangle. Examples of the quadrangular shape of the outer shape of the light-emitting element 10 in top view include a square shape and a rectangular shape.

The light-transmissive member 20 is disposed on the light-emitting element 10. The light-transmissive member 20 transmits light emitted from the light-emitting element 10. The light-transmissive member 20 may include a wavelength conversion member. For example, the light-transmissive member 20 may contain a phosphor. The light-transmissive member 20 may further contain a light-transmissive material such as aluminum oxide or aluminum nitride. The phosphor includes, for example, at least one of an oxide phosphor, a nitride phosphor, and an oxynitride phosphor. Examples of the oxide phosphor include a yttrium-aluminum-garnet-based phosphor (for example, (Y,Gd)₃(Al,Ga)₅O₁₂:Ce), lutetium-aluminum-garnet-based phosphor (for example, Lu₃(Al,Ga)₅O₁₂:Ce), and terbium-aluminum-garnet-based phosphor (for example, Tb₃(Al,Ga)₅O₁₂:Ce). Examples of the nitride phosphor include an LSN-based phosphor (for example., (La,Y)₃ Si₆N₁₁:Ce), a BSESN-based phosphor (for example, (Ba,Sr)₂Si₅N₈:Eu), an SLA-based phosphor (for example, SrLiAl₃N₄:Eu), a CASN-based phosphor (for example, CaAlSiN₃:Eu), and a SCASN-based phosphor (for example, (Sr,Ca)AlSiN₃:Eu). Examples of the oxynitride phosphor include a β-sialon-based phosphor (for example, (Si,Al)₃(O,N)₄:Eu) and an α-sialon-based phosphor (for example, Ca(Si,Al)₁₂(O,N)₁₆:Eu), and BSiON. The light-transmissive member 20 is preferably a sintered compact containing a YAG-based phosphor, for example. The light-transmissive member 20 may be a sintered compact of a composite material containing a phosphor and a light-transmissive material.

The light-transmissive member 20 has a second upper surface 21, a second lower surface 22, and second lateral surfaces 23. The second lateral surfaces 23 connect the second upper surface 21 and the second lower surface 22. In the light-emitting device 100, the second lower surface 22 is a surface parallel to the second upper surface 21. In the light-emitting device 100, the second upper surface 21 and the second lower surface 22 are flat surfaces along the X-Y plane.

Each of the second lateral surfaces 23 includes a first region 23a. The first region 23a is inclined toward a center C of the second lower surface 22 as extending downward. The first region 23a is inclined with respect to the first upper surface 11. The first region 23a is a flat surface or a curved surface. The first region 23a is preferably a curved surface.

As illustrated in FIG. 3, in the light-emitting device 100, the first region 23a is a curved surface. In the light-emitting device 100, the first region 23a is a curved surface whose inclination angle with respect to a horizontal plane (that is, the X-Y plane) increases from an upper end toward a lower end thereof. That is, in the light-emitting device 100, the first region 23a is a curved surface whose inclination angle with respect to the horizontal plane increases from an outer periphery toward a center thereof.

When a distance between a pair of second lateral surfaces 23 facing each other is defined as a width W of the light-transmissive member 20, the width W of the light-transmissive member 20 at the lower end of the first region 23a is smaller than the width W of the light-transmissive member 20 at the upper end of the first region 23a.

In the light-emitting device 100, each of the second lateral surfaces 23 further includes a second region 23b. The second region 23b is connected to the first region 23a. The second region 23b is located above the first region 23a. The second region 23b extends in a plane along the Z direction (that is, the up-down direction). That is, the second region 23b extends in a plane perpendicular to the second upper surface 21 and the second lower surface 22. The second lateral surface 23 need not include the second region 23b. The second lateral surface 23 may also have a step portion located above the second region 23b and recessed toward the center of the second upper surface 21.

In a top view, an outer peripheral end 23e of the second lateral surface 23 overlaps an outer peripheral end 13e of the first lateral surface 13. In top view, the outer peripheral end 23e of the second lateral surface 23 is an outermost portion of the second lateral surface 23. In the light-emitting device 100, the upper end of the first region 23a and the entire second region 23b of the second lateral surface 23 correspond to the outer peripheral end 23e of the second lateral surface 23. In top view, the outer peripheral end 13e of the first lateral surface 13 is an outermost portion of the first lateral surface 13. In the light-emitting device 100, an entirety of a first lateral surface 13 corresponds to the outer peripheral end 13e of the first lateral surface 13.

In top view, an outer peripheral end 22e of the second lower surface 22 overlaps a lower end 23f of the first region 23a. In top view, the outer peripheral end 22e of the second lower surface 22 is an outermost portion of the second lower surface 22. In the light-emitting device 100, the first region 23a is connected to the second lower surface 22. That is, in the light-emitting device 100, the lower end 23f of the first region 23a coincides with the outer peripheral end 22e of the second lower surface 22.

In the light-emitting device 100, the outer shape of the light-transmissive member 20 in a top view is a quadrangle. More specifically, the outer shape of the light-transmissive member 20 in top view is a quadrangle having a first side 20a, a second side 20b, a third side 20c, and a fourth side 20d. The second side 20b connects one end of the first side 20a and one end of the third side 20c. The fourth side 20d connects the other end of the first side 20a and the other end of the third side 20c. That is, the first side 20a and the third side 20c face each other, and the second side 20b and the fourth side 20d face each other. In the light-emitting device 100, the first side 20a and the third side 20c extend along the X direction, and the second side 20b and the fourth side 20d extend along the Y direction. The outer shape of the light-transmissive member 20 in top view may be, for example, a polygon other than a quadrangle. Examples of the quadrangular shape of the outer shape of the light-transmissive member 20 in top view include a square shape and a rectangular shape.

In the light-emitting device 100, the first regions 23a extend along the first side 20a, the second side 20b, the third side 20c, and the fourth side 20d. That is, in the light-emitting device 100, each first region 23a extends along a respective one of the four sides (that is, the first side 20a to the fourth side 20d) of the outer shape (that is, a quadrangle) of the light-transmissive member 20 in top view.

The light-emitting device 100 further includes an adhesive 30, a light reflecting member 40, a substrate 50, and an electrode 60. Instead of the use of the adhesive 30, the light-emitting element 10 and the light-transmissive member 20 may be directly bonded to each other without the adhesive 30 interposed therebetween.

The adhesive 30 bonds the light-emitting element 10 and the light-transmissive member 20 together. The adhesive 30 is located between the light-emitting element 10 and the light-transmissive member 20 in the Z direction. More specifically, the adhesive 30 is located between the first upper surface 11 of the light-emitting element 10 and the second lower surface 22 of the light-transmissive member 20 in the Z direction. The adhesive 30 may be, for example, polysilazane, silicone resin, or epoxy resin. Among these resins, polysilazane is a resin having a high refractive index, and increases the light extraction efficiency.

The light reflecting member 40 reflects light emitted from the light-emitting element 10 and the light emitted from the light-emitting element 10 and transmitted through the light-transmissive member 20. The light reflecting member 40 surrounds the periphery of the light-emitting element 10 and the periphery of the light-transmissive member 20. The light reflecting member 40 is in contact with the first lateral surfaces 13 of the light-emitting element 10 and the second lateral surfaces 23 of the light-transmissive member 20. A part of the light reflecting member 40 is located between the first upper surface 11 and the first region 23a in the Z direction. The light reflecting member 40 contains, for example, a resin and a light reflecting material. The resin may be, for example, a thermosetting resin such as a silicone resin or an epoxy resin. The light reflecting material may be, for example, particles made of an oxide such as titanium oxide, silicon oxide, or aluminum oxide, or metal particles of aluminum or the like. Instead of the resin, the light reflecting member 40 may be a ceramic made of an inorganic material.

The substrate 50 is located below the light-emitting element 10. The substrate 50 is a wiring substrate and is electrically connected to the electrode 60. The substrate 50 is preferably a ceramic having high heat resistance and thermal conductivity. The substrate 50 may be, for example, aluminum nitride, silicon nitride, silicon carbide, or the like.

The electrode 60 is located between the substrate 50 and the first lower surface 12 of the light-emitting element 10 in the Z direction. The light-emitting element 10 is electrically connected to the substrate 50 via the electrode 60. As the electrode 60, for example, Au or an alloy thereof, eutectic solder (Au—Sn), a conductive paste containing metal particles, or the like can be used.

### First Modified Example

FIG. 4 is a schematic cross-sectional view illustrating a part of a light-emitting device according to a first modified example of the first embodiment.

As illustrated in FIG. 4, the first region 23a may be a curved surface whose inclination angle with respect to the horizontal plane decreases from the upper end toward the lower end thereof. That is, the first region 23a may be a curved surface whose inclination angle with respect to the horizontal plane decreases from the outer periphery toward the center thereof. In addition, the first region 23a may include both the curved surface illustrated in FIG. 3 and the curved surface illustrated in FIG. 4.

### Second Modified Example

FIG. 5 is a schematic cross-sectional view illustrating a part of a light-emitting device according to a second modified example of the first embodiment.

As illustrated in FIG. 5, the first region 23a may be a plane having a uniform inclination angle with respect to the horizontal plane.

### Third Modified Example

FIG. 6 is a schematic cross-sectional view illustrating a part of a light-emitting device according to a third modified example of the first embodiment.

As illustrated in FIG. 6, the first region 23a need not be connected to the second lower surface 22. Each second lateral surface 23 may further include a third region 23c. The third region 23c is connected to the first region 23a. The third region 23c is located below the first region 23a. The third region 23c extends in a plane along the Z direction. That is, the third region 23c extends in a plane perpendicular to the second upper surface 21 and the second lower surface 22. The first region 23a may have any shape described above. In the third modified example, the lower end 23f of the first region 23a is located above the outer peripheral end 22e of the second lower surface 22. In top view, the outer peripheral end 22e of the second lower surface 22 overlaps the lower end 23f of the first region 23a.

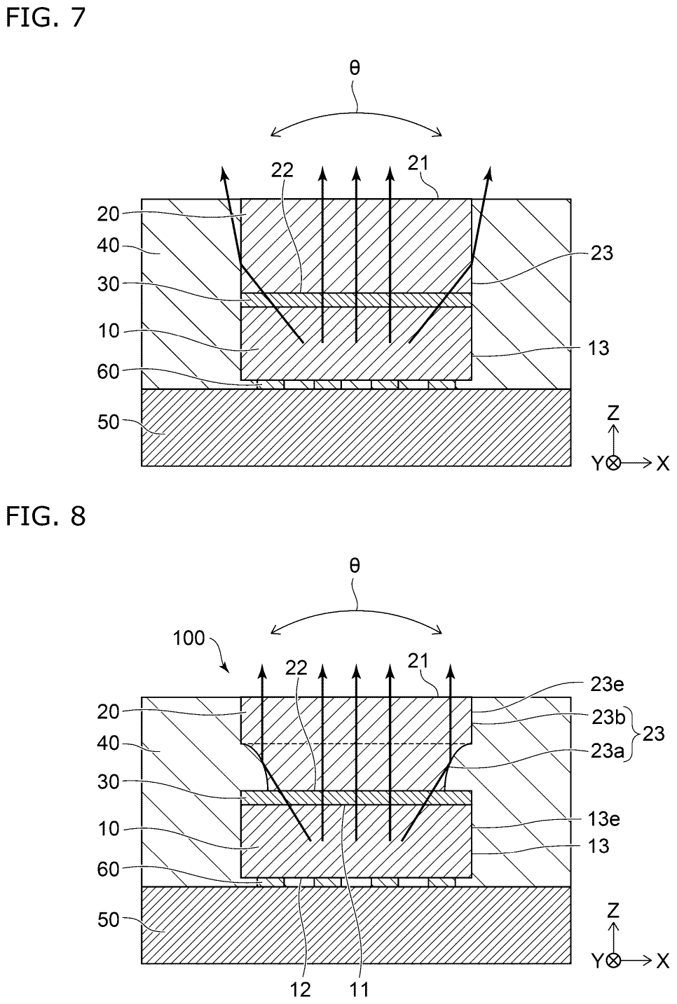

The effects of the light-emitting device according to the first embodiment are described below. FIG. 7 is a schematic cross-sectional view illustrating light emission in a light-emitting device in the related art. FIG. 8 is a schematic cross-sectional view illustrating light emission in the light-emitting device according to the first embodiment.

In FIGS. 7 and 8, the direction in which light is emitted is indicated by an arrow.

As illustrated in FIG. 7, in a light-emitting device in the related art, the second lateral surface 23 of the light-transmissive member 20 does not include the first region 23a. The second lateral surfaces 23 face in the X direction and extends upward (that is, in the Z direction). Therefore, light emitted obliquely upward from the light-emitting element 10 is less likely to be extracted upward, and is likely to be emitted laterally from the second lateral surface 23. Consequently, a light distribution angle θ in the cross-sectional view illustrated in FIG. 7 is likely to increase (for example, about 120°), and the proportion of light that exits upward from the second upper surface 21 of the light-transmissive member 20 is small, so that the luminance is likely to decrease.

On the other hand, as illustrated in FIG. 8, in the light-emitting device 100 according to the first embodiment, each of the second lateral surfaces 23 of the light-transmissive member 20 includes the first region 23a facing upward, so that light emitted obliquely upward from the light-emitting element 10 can be reflected upward in the first region 23a.

Thus, the light emitted obliquely upward from the light-emitting element 10 is less likely to be emitted laterally from the second lateral surface 23, and the light distribution angle θ in the cross-sectional view illustrated in FIG. 8 can be made smaller (for example, about 105° to 115°) than that in the light-emitting device in the related art. Consequently, the proportion of light emitted upward from the second upper surface 21 of the light-transmissive member 20 is increased, so that the luminance can be enhanced. In addition, because the outer peripheral end 23e of the second lateral surface 23 overlaps the outer peripheral end 13e of the first lateral surface 13 in top view, the size of the light-emitting element 10 and the size of the light-transmissive member 20 can coincide with each other in top view. This prevents the light-emitting element 10 from being larger than the light-transmissive member 20 in top view, thereby reducing the likelihood that light emitted upward from the light-emitting element 10 exits from the upper surface of the light-emitting device 100 without passing through the light-transmissive member 20. In addition, because the light-emitting element 10 is not smaller than the light-transmissive member 20 in top view, the luminance of the outer peripheral portion of the light-transmissive member 20 is less likely to decrease. In addition, because the outer peripheral end 22e of the second lower surface 22 overlaps the lower end 23f of the first region 23a in top view, light emitted from the light-emitting element 10 can be efficiently incident on the light-transmissive member 20.

In addition, in the light-emitting device 100, each of the second lateral surfaces 23 of the light-transmissive member 20 further includes the second region 23b, so that light emitted obliquely upward from the light-emitting element 10 can be reflected to the central portion of the second region 23b in top view. Thus, the proportion of light that exits upward from the vicinity of the center of the second upper surface 21 of the light-transmissive member 20 is increased, so that the luminance of the center portion can be enhanced. Consequently, the efficiency of incidence on a secondary optical system, which may be disposed in a subsequent stage of the light-emitting device 100, can be improved.

In addition, in the light-emitting device 100, by forming the first region 23a as a curved surface, light emitted obliquely upward from the light-emitting element 10 is easily reflected upward in the first region 23a. Thus, the proportion of light that exits upward from the second upper surface 21 of the light-transmissive member 20 is further increased, so that the luminance can be further increased.

In addition, in the light-emitting device 100, the first region 23a extends along each of the four sides of the outer shape (that is, a quadrangle) of the light-transmissive member 20 in top view, so that light emitted from the light-emitting element 10 in the direction of each side can be reflected upward in the first region 23a. Thus, the proportion of light that exits upward from the second upper surface 21 of the light-transmissive member 20 is further increased, so that the luminance can be further increased. In the light-emitting device 100, the light distribution angles in the X direction and the Y direction can be efficiently narrowed as compared with those in the light-emitting device illustrated in FIG. 7 in the related art. Consequently, the efficiency of incidence on a secondary optical system, which may be disposed in a subsequent stage of the light-emitting device 100, can be enhanced. For example, the light-emitting device 100 may be used in a vehicle lamp to form a light distribution of a low beam or a high beam.

In addition, in the light-emitting device 100, because the light-transmissive member 20 contains a phosphor, both light (excitation light) emitted from the light-emitting element 10 and light subjected to wavelength conversion by the phosphor can be efficiently extracted.

In addition, in the light-emitting device 100, because the phosphor contains at least one of an oxide phosphor, a nitride phosphor, and an oxynitride phosphor, light (excitation light) emitted from the light-emitting element 10 and light subjected to wavelength conversion by the phosphor can be mixed to obtain light of a desired color. The light-emitting device 100 emits, for example, white light by mixing the excitation light and the wavelength-converted light. The color temperature (also including correlated color temperature) of the white light is in a range from 3000 K to 7000 K, for example.

In addition, in the light-emitting device 100, the light reflecting member 40 is in contact with the first lateral surfaces 13 and the second lateral surfaces 23 and is located between the first upper surface 11 and the first region 23a in the up-down direction. This facilitates upward reflection of light emitted obliquely upward from the light-emitting elements 10 in the first region 23a (that is, an interface between the light-transmissive member 20 and the light reflecting member 40). Thus, the proportion of light that exits upward from the second upper surface 21 of the light-transmissive member 20 is further increased, so that the luminance can be further increased.

Light-emitting devices to be described using second to sixth embodiments are examples in which the first region 23a is provided at a predetermined side or a predetermined corner of the outer shape of the light-emitting device in top view. Thus, a light distribution angle with respect to the direction from the center of the light-emitting device toward the first region 23a can be made smaller than a light distribution angle with respect to the direction from the center of the light-emitting device toward a side where the first region 23a is not provided. In this way, by providing the first region 23a at a side or a corner corresponding to a specific direction in which the light distribution is desired to be narrowed, the light distribution in the direction can be efficiently narrowed. Each example is described below.

### Second Embodiment

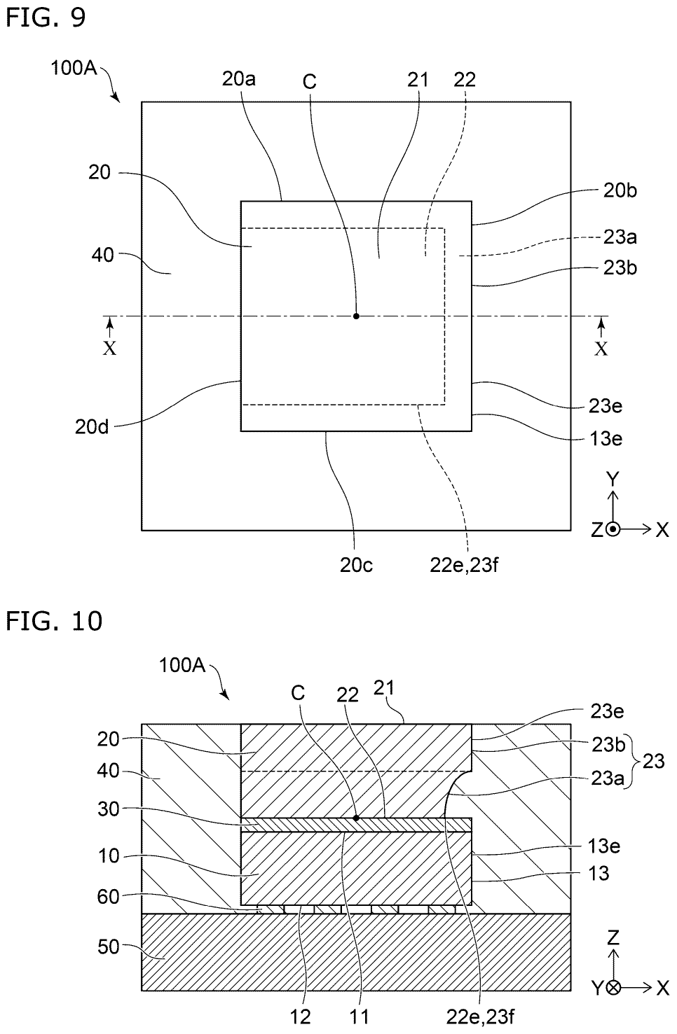

FIG. 9 is a schematic plan view illustrating the light-emitting device according to the second embodiment. FIG. 10 is a schematic cross-sectional view illustrating the light-emitting device according to the second embodiment. FIG. 10 illustrates a cross-section taken along line X-X in FIG. 9.

As illustrated in FIGS. 9 and 10, a light-emitting device 100A according to the second embodiment is substantially the same as the light-emitting device 100 according to the first embodiment except in the shape of the first region 23a of the light-transmissive member 20.

In the light-emitting device 100A, the first region 23a extends along the first side 20a, the second side 20b, and the third side 20c of the outer shape (that is, a quadrangle) of the light-transmissive member 20 in top view. That is, in the light-emitting device 100A, the first region 23a extends along three sides among the four sides (that is, the first side 20a to the fourth side 20d) of the outer shape (that is, a quadrangle) of the light-transmissive member 20 in top view.

Also in the light-emitting device 100A, with the second lateral surfaces 23 of the light-transmissive member 20 each including the first region 23a, the proportion of light that exits upward from the second upper surface 21 of the light-transmissive member 20 is increased, so that the luminance can be enhanced.

In addition, in the light-emitting device 100A, because the first region 23a extends along the three sides, a light distribution angle in a direction including the first region 23a can be made smaller than a light distribution angle in a direction (that is, −X direction) not including the first region 23a. Thus, when the light-emitting device 100A is turned on, light is spread in the −X direction, and visibility from the −X direction can be enhanced. The light-emitting device 100A is preferably applied to a lamp or an outdoor display. The cost of an outdoor display can be reduced by providing no light-shielding louver in a lamp or an outdoor display or reducing the size of a light-shielding louver provided therein.

### Third Embodiment

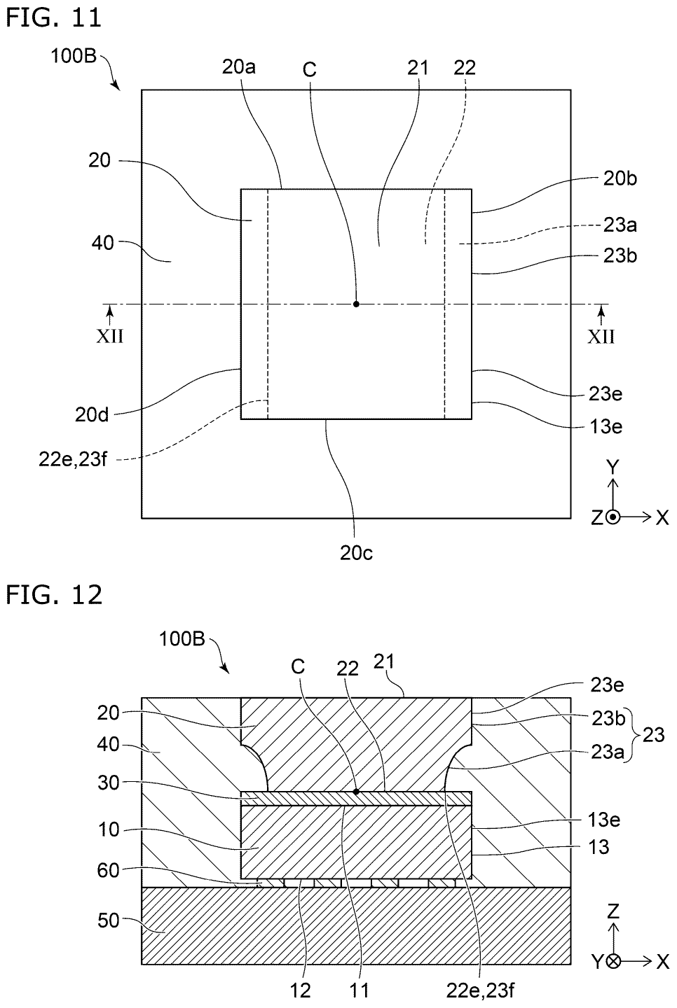

FIG. 11 is a schematic plan view illustrating the light-emitting device according to the third embodiment. FIG. 12 is a schematic cross-sectional view illustrating the light-emitting device according to the third embodiment. FIG. 12 illustrates a cross-section taken along line XII-XII in FIG. 11.

As illustrated in FIGS. 11 and 12, a light-emitting device 100B according to the third embodiment is substantially the same as the light-emitting device 100 according to the first embodiment except in the shape of the first region 23a of the light-transmissive member 20.

In the light-emitting device 100B, the first regions 23a extend along the second side 20b and the fourth side 20d of the outer shape (that is, a quadrangle) of the light-transmissive member 20 in top view. That is, in the light-emitting device 100B, the first regions 23a extend along two sides facing each other among the four sides (that is, the first side 20a to the fourth side 20d) of the outer shape (that is, quadrangle) of the light-transmissive member 20 in top view.

Also in the light-emitting device 100B, with the second lateral surfaces 23 of the light-transmissive member 20 each including the first region 23a, the proportion of light that exits upward from the second upper surface 21 of the light-transmissive member 20 is increased, so that the luminance can be enhanced.

In addition, in the light-emitting device 100B, the first regions 23a extend along two sides facing each other, so that a light distribution angle in the X direction can be efficiently narrowed. Consequently, the light distribution angle in the X direction can be relatively narrowed, so that a light distribution angle in the Y direction perpendicular to the X direction can be relatively widened. Consequently, the efficiency of incidence on a secondary optical system, which may be disposed in a subsequent stage of the light-emitting device 100B, can be enhanced. For example, the light-emitting device 100B may be used in a vehicle lamp to form a low-beam light distribution.

In top view, the outer shape of the light-emitting element 10 and the outer shape of the light-transmissive member 20 may be a rectangle having a long side in the Y direction and a short side in the X direction. Thus, the aspect ratio of the first upper surface 11 of the light-emitting element 10 and the aspect ratio of the second upper surface 21 of the light-transmissive member 20 can make the light distribution angle with respect to the X direction narrower than the light distribution angle with respect to the Y direction. Together with the effect of the aspect ratios and the effect of the first region 23a, the light distribution angle with respect to the X direction can be made smaller than the light distribution angle with respect to the Y direction.

### Fourth Embodiment

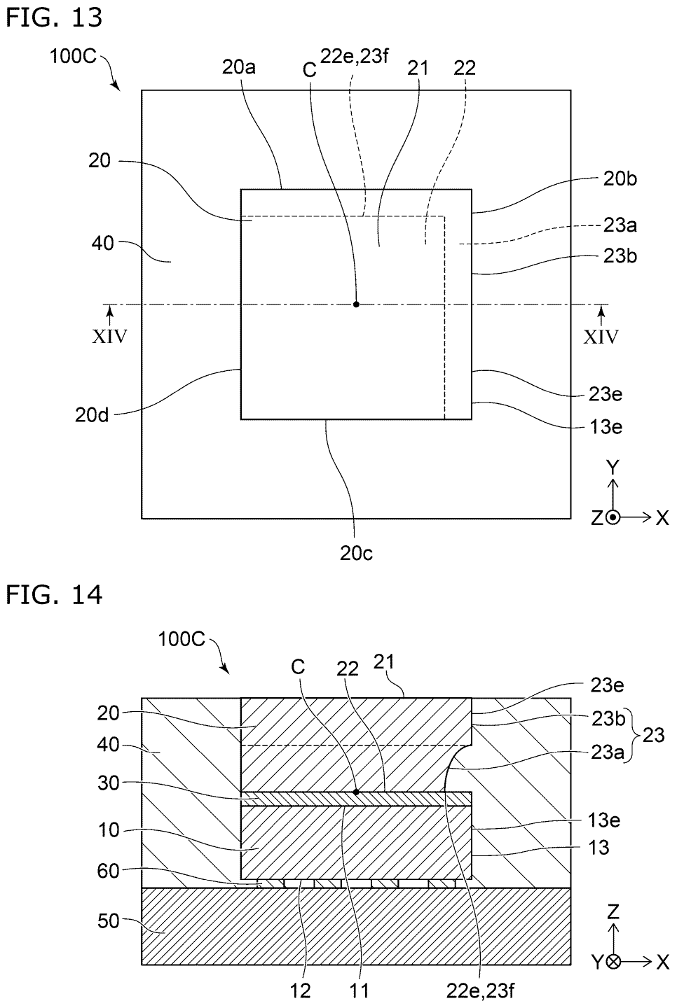

FIG. 13 is a schematic plan view illustrating the light-emitting device according to the fourth embodiment. FIG. 14 is a schematic cross-sectional view illustrating the light-emitting device according to the fourth embodiment. FIG. 14 illustrates a cross-section taken along line XIV-XIV in FIG. 13.

As illustrated in FIGS. 13 and 14, a light-emitting device 100C according to the fourth embodiment is substantially the same as the light-emitting device 100 according to the first embodiment except in the shape of the first region 23a of the light-transmissive member 20.

In the light-emitting device 100C, the first regions 23a extend along the first side 20a and the second side 20b of the outer shape (that is, a quadrangle) of the light-transmissive member 20 in top view. That is, in the light-emitting device 100C, the first regions 23a extend along two sides adjacent to each other among the four sides (that is, the first side 20a to the fourth side 20d) of the outer shape (that is, a quadrangle) of the light-transmissive member 20 in top view.

Also in the light-emitting device 100C, with the second lateral surfaces 23 of the light-transmissive member 20 each including the first region 23a, the proportion of light that exits upward from the second upper surface 21 of the light-transmissive member 20 is increased, so that the luminance can be enhanced.

In addition, in the light-emitting device 100C, the first regions 23a extend along two sides adjacent to each other, so that emission light having an L-shaped luminance distribution is obtained. Consequently, the cost of a lamp or an outdoor display can be reduced by changing a lamp or an outdoor display to a simple one having a lowered height of a light-shielding louver.

### Fifth Embodiment

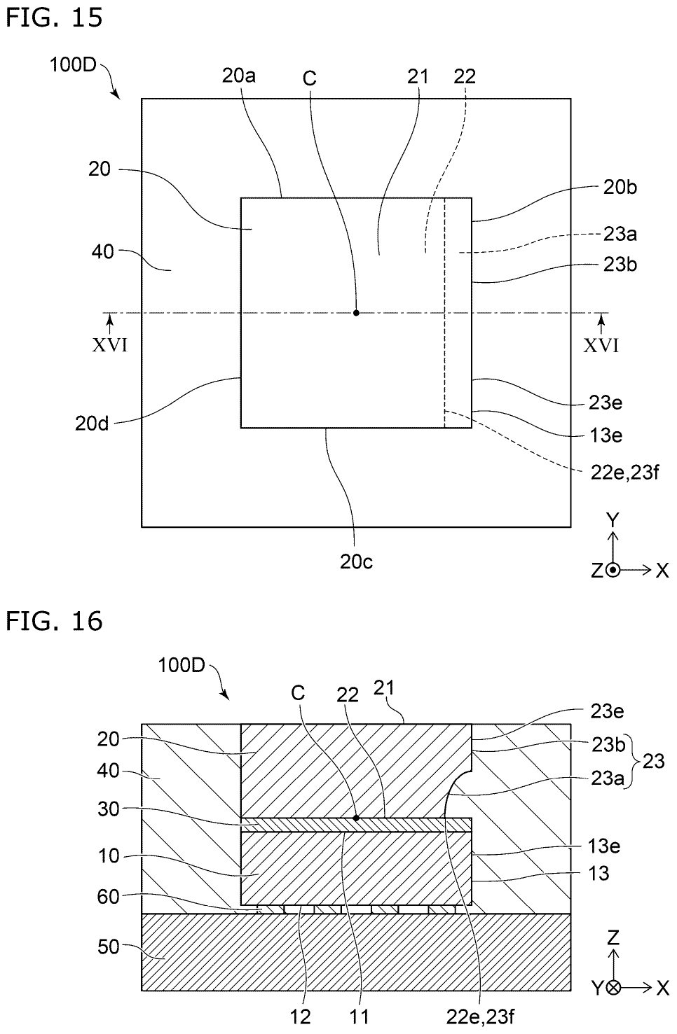

FIG. 15 is a schematic plan view illustrating the light-emitting device according to the fifth embodiment. FIG. 16 is a schematic cross-sectional view illustrating the light-emitting device according to the fifth embodiment. FIG. 16 illustrates a cross-section taken along line XVI-XVI in FIG. 15.

As illustrated in FIGS. 15 and 16, a light-emitting device 100D according to the fifth embodiment is substantially the same as the light-emitting device 100 according to the first embodiment except in the shape of the first region 23a of the light-transmissive member 20.

In the light-emitting device 100D, the first region 23a extends along the second side 20b of the outer shape (that is, a quadrangle) of the light-transmissive member 20 in top view. That is, in the light-emitting device 100D, the first region 23a extends along one of the four sides (that is, the first side 20a to the fourth side 20d) of the outer shape (that is, a quadrangle) of the light-transmissive member 20 in top view.

Also in the light-emitting device 100D, with the second lateral surfaces 23 of the light-transmissive member 20 each including the first region 23a, the proportion of light that exits upward from the second upper surface 21 of the light-transmissive member 20 is increased, so that the luminance can be enhanced.

In addition, in the light-emitting device 100D, because the first region 23a extends along one side, the difference in luminance between a side on which the first region 23a is formed and a side on which the first region 23a is not formed can be increased, so that an irradiation image with contrast is obtained.

### Sixth Embodiment

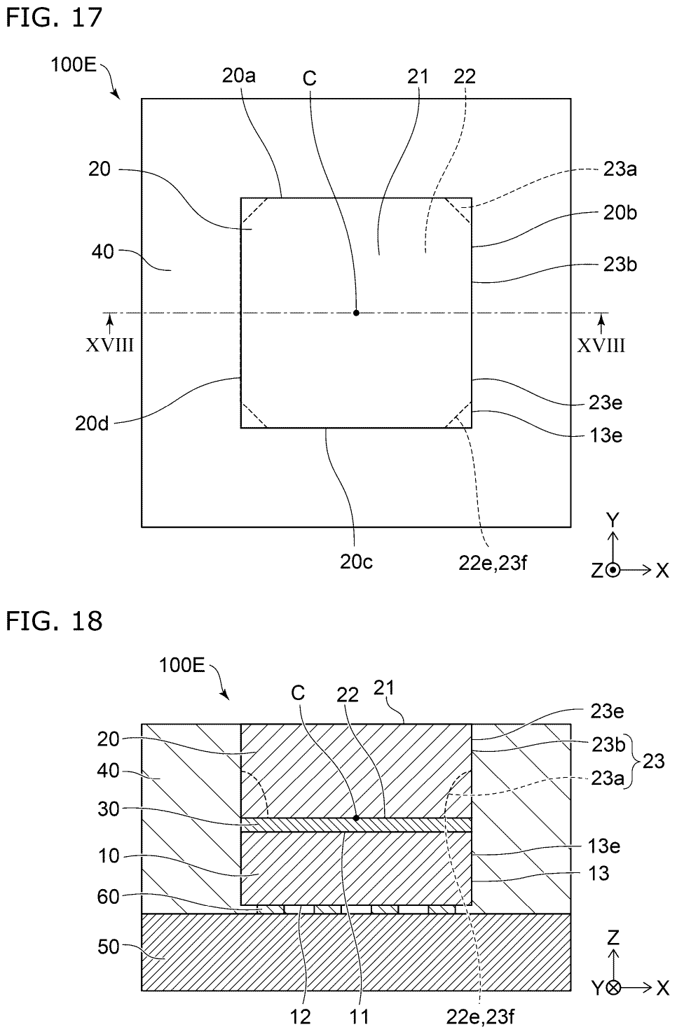

FIG. 17 is a schematic plan view illustrating the light-emitting device according to the sixth embodiment. FIG. 18 is a schematic cross-sectional view illustrating the light-emitting device according to the sixth embodiment. FIG. 18 illustrates a cross section taken along line XVIII-XVIII in FIG. 17.

As illustrated in FIGS. 17 and 18, a light-emitting device 100E according to the sixth embodiment is substantially the same as the light-emitting device 100 according to the first embodiment except in the shape of the first region 23a of the light-transmissive member 20.

In the light-emitting device 100E, the first region 23a is disposed at each of four corners at which the four sides (that is, the first side 20a to the fourth side 20d) of the outer shape (that is, a quadrangle) of the light-transmissive member 20 in top view intersect each other.

Also in the light-emitting device 100E, with the second lateral surfaces 23 of the light-transmissive member 20 each including the first region 23a, the proportion of light that exits upward from the second upper surface 21 of the light-transmissive member 20 is increased, so that the luminance can be enhanced.

In addition, in the light-emitting device 100E, the first regions 23a are disposed at the four corners, so that a light distribution angle in a direction shifted by 45° with respect to each of the X direction and the Y direction can be reduced.

### Method for Manufacturing Light-Emitting Device

### First Embodiment

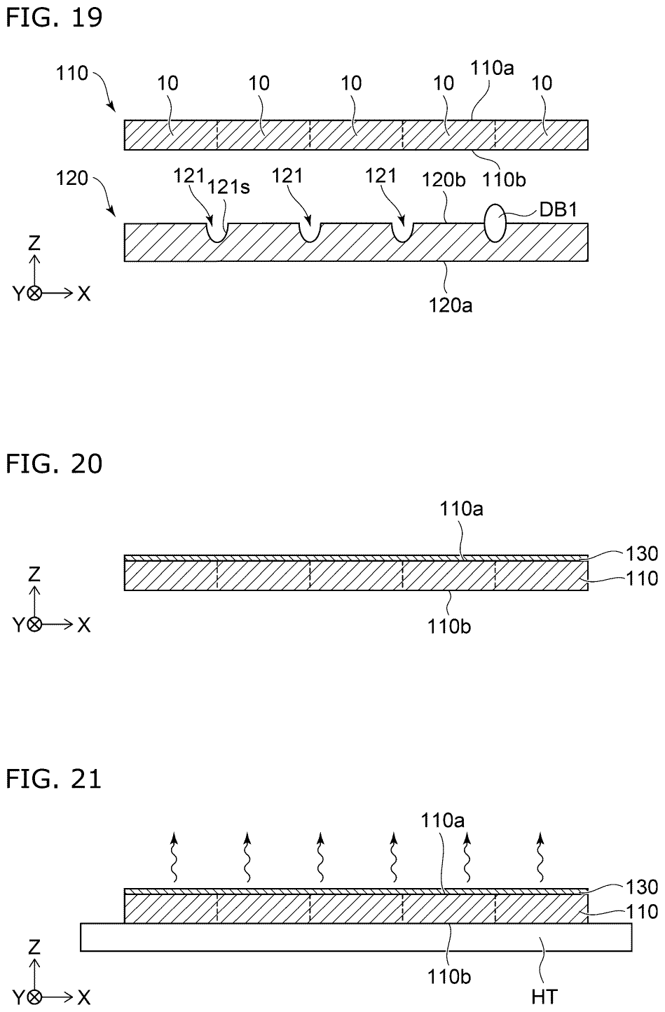

FIG. 19 is a schematic cross-sectional view illustrating a first step of a method for manufacturing the light-emitting device according to the first embodiment.

FIGS. 20 to 23 are schematic cross-sectional views illustrating a second step of the method for manufacturing the light-emitting device according to the first embodiment.

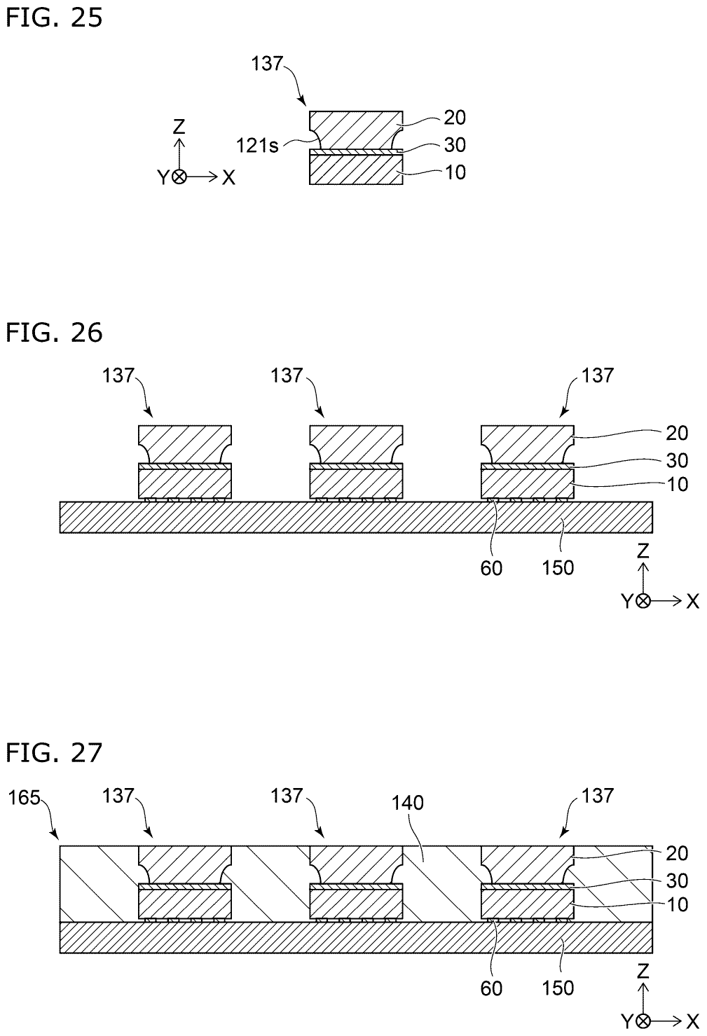

FIGS. 24 and 25 are schematic cross-sectional views illustrating a third step of the method for manufacturing the light-emitting device according to the first embodiment. FIG. 26 is a schematic cross-sectional view illustrating a fourth step of the method for manufacturing the light-emitting device according to the first embodiment. FIG. 27 is a schematic cross-sectional view illustrating a fifth step of the method for manufacturing the light-emitting device according to the first embodiment.

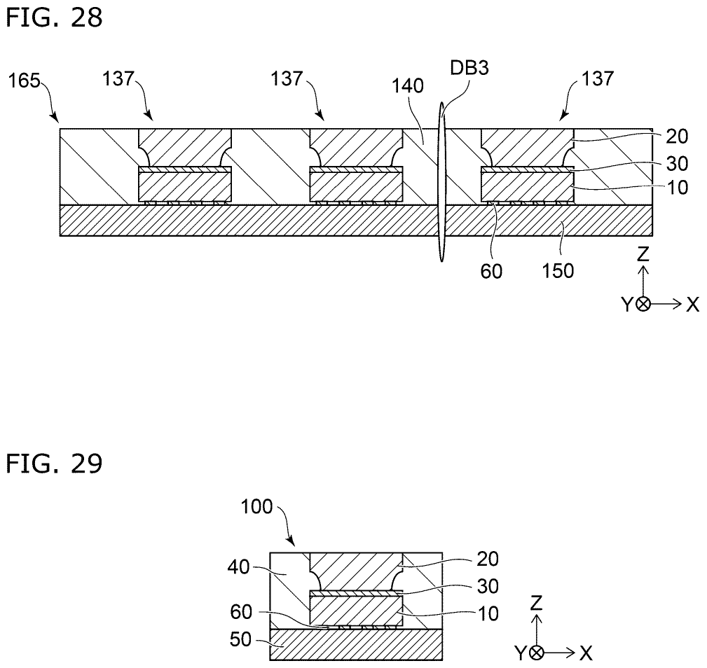

FIGS. 28 to 29 are schematic cross-sectional views illustrating a sixth step of the method for manufacturing the light-emitting device according to the first embodiment.

FIGS. 19 to 29 are schematic cross-sectional views perpendicular to a light-emitting surface of the light-emitting device. The directions of cross sections in FIGS. 19 to 29 correspond to, for example, the direction of the cross section at the position of the line II-II illustrated in FIG. 1.

As illustrated in FIGS. 19 to 29, the method for manufacturing the light-emitting device according to the first embodiment includes the first to sixth steps. The first to sixth steps are performed in the order of the first step, the second step, the third step, the fourth step, the fifth step, and the sixth step.

As illustrated in FIG. 19, in the first step, a wafer 110 and a light-transmissive substrate 120 are provided. The wafer 110 includes a plurality of light-emitting elements 10. The wafer 110 is divided into the light-emitting elements 10 described above. The wafer 110 has a first main surface 110a and a first rear surface 110b. The light-transmissive substrate 120 is divided into the light-transmissive members 20 described above. The light-transmissive substrate 120 has a second main surface 120a and a second rear surface 120b.

In the first step, the light-transmissive substrate 120 having the second rear surface 120b provided with slits 121 is provided. The slit 121 is formed by, for example, removing a part of the second rear surface 120b side of the light-transmissive substrate 120 by a dicing blade DB1. The slit 121 may also be referred to as a groove.

The slit 121 has an inclined surface 121s inclined widening from the second main surface 120a toward the second rear surface 120b. In the cross-sectional view, the inclined surfaces 121s are connected at the bottom of the slit 121. The inclined surface 121s is a flat surface or a curved surface. The inclined surface 121s corresponds to the first region 23a of the second lateral surface 23 of the light-transmissive member 20 described above. The width of the slit 121 is preferably in a range from 0.05 mm to 0.5 mm. The width refers to the dimension of the thickest portion. The depth of the slit 121 is preferably in a range from 0.05 mm to 0.5 mm. The depth refers to the dimension from the second rear surface 120b to the deepest portion of the slit 121. The slit 121 is described below. When a low refractive index member is disposed in contact with the first region 23a, a material of the low refractive index member is disposed inside the slit 121. In addition, after the slits 121 are formed, the second main surface 120a may be polished such that the second region 23b of the light-transmissive member 20 after the singulation is thinner than that before the polishing.

As illustrated in FIGS. 20 to 23, in the second step, a structure 135 is formed. As illustrated in FIG. 20, in the second step, an adhesive layer 130 is first formed on the first main surface 110a of the wafer 110. The adhesive layer 130 is divided into the adhesives 30 described above. The adhesive layer 130 is formed by applying a material with a spin coater, for example.

As illustrated in FIG. 21, subsequently, in the second step, the wafer 110 having the first main surface 110a on which the adhesive layer 130 is formed is heated by a heater HT to volatilize a solvent and the like contained in the adhesive layer 130. The heater HT is, for example, a hot plate. The heating condition may be in a range from 80° C. to 200° C., for example. By performing this step, gas generated at the time of curing the adhesive layer 130 can be reduced.

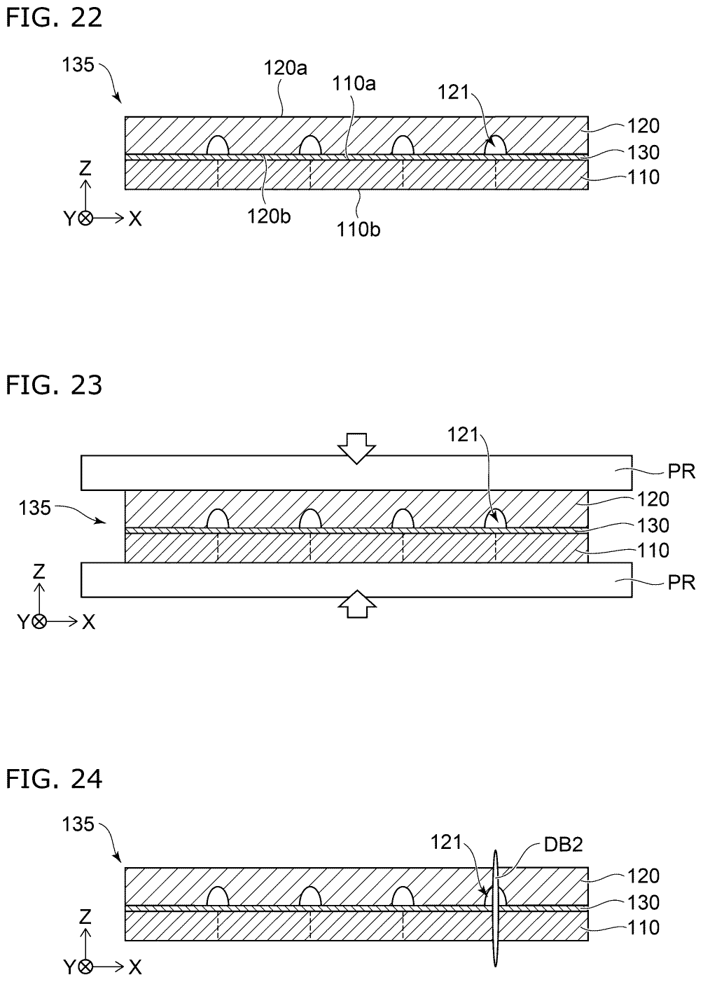

As illustrated in FIG. 22, subsequently, in the second step, the second rear surface 120b of the light-transmissive substrate 120 is bonded to the first main surface 110a of the wafer 110 via the adhesive layer 130. Thus, the structure 135 in which the light-transmissive substrate 120 is bonded onto the wafer 110 is formed.

As illustrated in FIG. 23, subsequently, in the second step, the structure 135 is heated and pressurized by a press machine PR to cure the adhesive layer 130. The heating condition may be in a range from 130° C. to 200° C. The pressurization condition may be in a range from 50 g/mm² to 200 g/mm². The heating and pressurization may be started at the same time, or one of them may be started first. In addition, the heating and pressurization may be ended at the same time, or one of them may be ended first. Note that the heating time of the adhesive layer 130 in this step is longer than the heating time for volatilizing the solvent from the adhesive layer 130 described with reference to FIG. 21.

As illustrated in FIGS. 24 and 25, in the third step, the wafer 110, the light-transmissive substrate 120, and the adhesive layer 130 are collectively subjected to singulation by dividing the structure 135 at a position overlapping the slit 121. The structure 135 can be divided by a dicing blade DB2, for example. The structure 135 is divided into individual structures 137. The structure 137 obtained by singulation includes the light-emitting element 10 obtained by dividing the wafer 110, the light-transmissive member 20 obtained by dividing the light-transmissive substrate 120, and the adhesive 30 obtained by dividing the adhesive layer 130. Before the singulation, the second main surface 120a of the light-transmissive substrate 120 may be polished to allow the second region 23b of the light-transmissive member 20 after the singulation to be thinner than that before the polishing.

The structure 135 is divided such that a part (that is, the inclined surface 121s) of the slit 121 remains in the light-transmissive substrate 120 (that is, the light-transmissive member 20) after the singulation. When the structure 135 is divided, a part of the structure 135 is cut and lost at the division position in some cases. A part of the structure 135 lost when the structure 135 is divided is a so-called “cutting margin.” For example, by making the width of the cutting margin smaller than the width of the slit 121, the structure 135 can be divided such that a part (that is, the inclined surface 121s) of the slit 121 remains in the light-transmissive substrate 120 (that is, the light-transmissive member 20) after the singulation.

As illustrated in FIG. 26, in the fourth step, the plurality of separated structures 137 are disposed on a mounting substrate 150 via the electrodes 60. The separated structures 137 are each disposed with the light-emitting element 10 facing downward. Thus, the light-emitting element 10 is electrically connected to the mounting substrate 150 via the electrode 60. Note that the mounting substrate 150 is divided into the substrates 50 described above.

As illustrated in FIG. 27, in the fifth step, a layered body 165 is formed by forming a light reflecting layer 140 around the plurality of separated structures 137 on the mounting substrate 150. The light reflecting layer 140 is divided into the light reflecting members 40 described above. The light reflecting layer 140 is formed by, for example, potting, compression molding, or transfer molding.

As illustrated in FIGS. 28 and 29, in the sixth step, the light reflecting layer 140 and the mounting substrate 150 are collectively subjected to singulation by dividing the layered body 165. The layered body 165 can be divided by a dicing blade DB3, for example. The layered body 165 is divided into the light-emitting devices 100. The light-emitting device 100 includes the light-emitting element 10, the light-transmissive member 20, the adhesive 30, the light reflecting member 40 obtained by dividing the light reflecting layer 140, the substrate 50 obtained by dividing the mounting substrate 150, and the electrode 60.

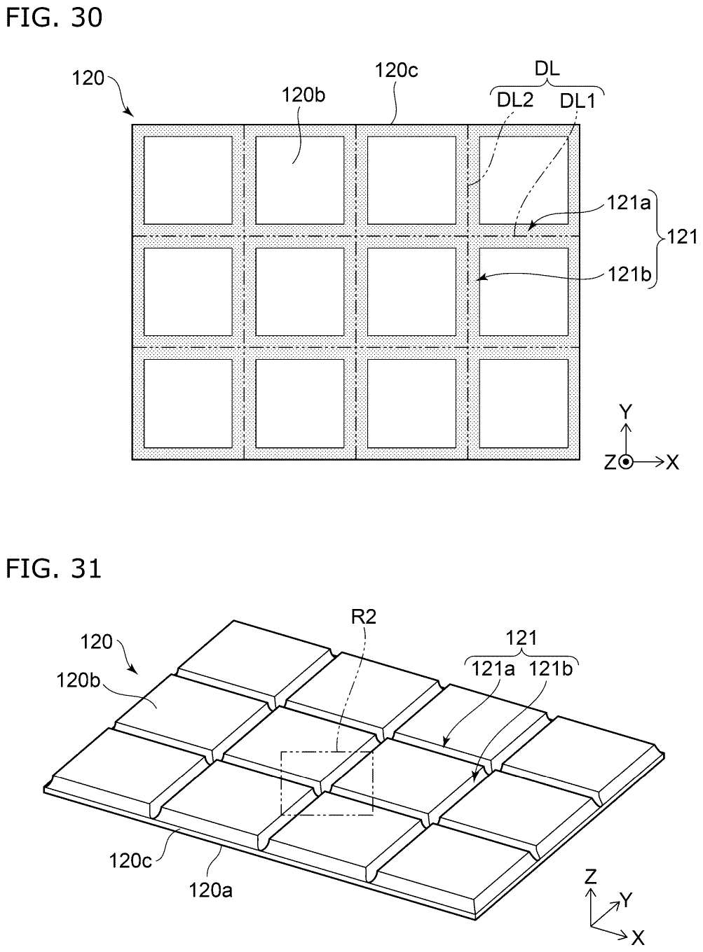

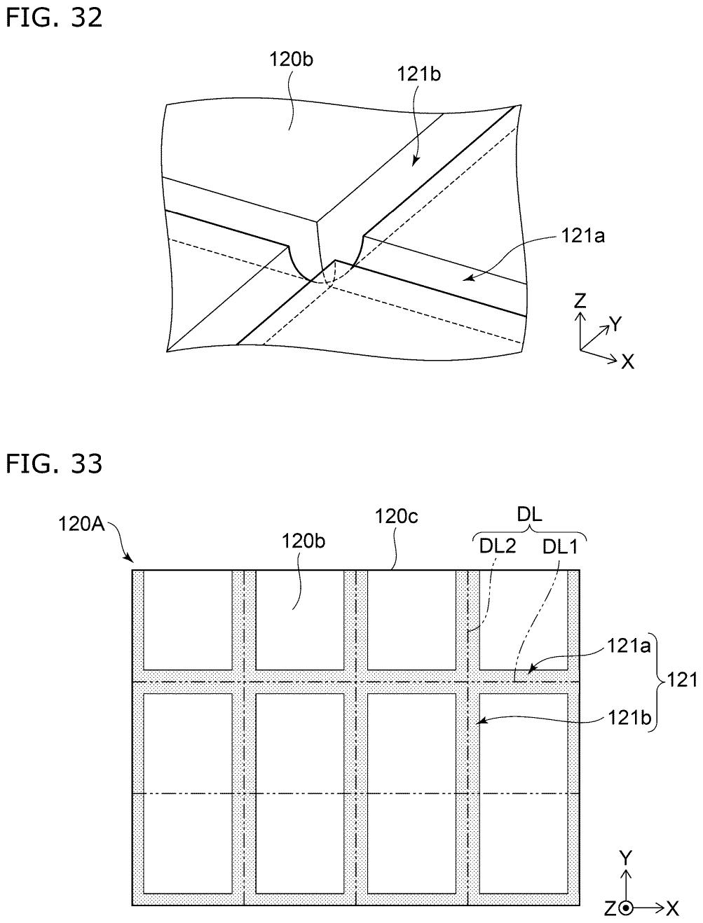

The slit 121 formed in the second rear surface 120b of the light-transmissive substrate 120 is described below. FIG. 30 is a schematic plan view illustrating the light-transmissive substrate in the method for manufacturing the light-emitting device according to the first embodiment. FIG. 31 is a schematic perspective view illustrating the light-transmissive substrate in the method for manufacturing the light-emitting device according to the first embodiment. FIG. 32 is a schematic perspective view illustrating a part of the light-transmissive substrate in the method for manufacturing the light-emitting device according to the first embodiment.

In FIG. 30, the positions where the slits 121 are formed are indicated by shading. In addition, in FIG. 30, the position where the structure 135 is divided in the third step (that is, a dividing line DL) is indicated by a two dot chain line. FIG. 32 illustrates an enlarged view of a region R2 illustrated in FIG. 31.

As illustrated in FIGS. 30 to 32, in the method for manufacturing the light-emitting device according to the first embodiment, in the first step, the light-transmissive substrate 120 provided with the slits 121 formed in a matrix form on the second rear surface 120b is provided.

In the first embodiment, the slit 121 includes a plurality of first slit regions 121a and a plurality of second slit regions 121b. The plurality of second slit regions 121b intersect corresponding ones of the plurality of first slit regions 121a. Each of the plurality of first slit regions 121a extends along the X direction. Each of the plurality of second slit regions 121b extends along the Y direction. As illustrated in FIG. 32, a structure in which curved surfaces intersect each other is formed at each of the intersections between the first slit region 121a and the second slit region 121b.

In addition, in the first step, the light-transmissive substrate 120 provided with the slits 121 connected to the lateral surface 120c of the light-transmissive substrate 120 is preferably provided. That is, the slits 121 preferably extend to the outside of the light-transmissive substrate 120. The lateral surface 120c connects the second main surface 120a and the second rear surface 120b.

As illustrated in FIG. 30, the dividing lines DL extend in a matrix form. The dividing lines DL include first dividing lines DL1 extending along the X direction and second dividing lines DL2 extending along the Y direction. In the first embodiment, the slits 121 are formed at all positions overlapping the first dividing lines DL1 and all the second dividing lines DL2. That is, in the first embodiment, part of the slits 121 remains on each of the four sides of the separated light-transmissive members 20. Thus, as illustrated in FIGS. 1 and 2, the light-emitting device 100, in which each of the first regions 23a extends along a respective one of the four sides (that is, the first side 20a to the fourth side 20d) of the outer shape (that is, a quadrangle) of the light-transmissive member 20 in top view, can be manufactured.

The effects of the method for manufacturing the light-emitting device according to the first embodiment are described below.

In the method for manufacturing the light-emitting device according to the first embodiment, the light-transmissive substrate 120 provided with the slits 121 formed on the second rear surface 120b is provided in the first step and the structure 135 is divided such that part (that is, the inclined surface 121s) of the slits 121 remains in the light-transmissive substrate 120 (that is, the light-transmissive member 20) after the singulation in the third step, thereby easily manufacturing the light-emitting device including the first region 23a formed in the second lateral surface 23 of the light-transmissive member 20. Thus, the light-emitting device with enhanced luminance can be easily manufactured.

In the third step, the wafer 110 and the light-transmissive substrate 120 are collectively subjected to singulation, so that the outer peripheral ends 23e of the second lateral surfaces 23 of the light-transmissive member 20 can overlap the outer peripheral ends 13e of the first lateral surfaces 13 of the light-emitting element 10 in the structure 137 obtained by singulation in top view.

In addition, in the method for manufacturing the light-emitting device according to the first embodiment, by providing the light-transmissive substrate 120 provided with the slits 121 formed in a matrix form on the second rear surface 120b in the first step, the light-emitting device, in which the first regions 23a extend along all of the four sides (that is, the first side 20a to the fourth side 20d) of the outer shape (that is, a quadrangle) of the light-transmissive member 20 in top view, can be manufactured.

In addition, in the method for manufacturing the light-emitting device according to the first embodiment, in the first step, the light-transmissive substrate 120 provided with the slits 121 connected to the lateral surface 120c of the light-transmissive substrate 120 is provided. Thus, when the second rear surface 120b is bonded to the first main surface 110a via the adhesive layer 130 in the second step, gas generated when the adhesive layer 130 is cured is exhausted to the outside of the structure 135 through the slit 121 formed on the second rear surface 120b. Consequently, the occurrence of adhesion failure such as voids due to gas generated when the adhesive layer 130 is cured can be reduced. In particular, in the method for manufacturing the light-emitting device according to the first embodiment, the slits 121 are formed in a matrix form such that all the slits 121 and all the positions of the dividing lines DL overlap each other. Thus, the gas from the adhesive layer 130 in the second step is efficiently exhausted to the outside from both the row direction and the column direction, so that the likelihood of the occurrence of voids can be further reduced.

In addition, in the method for manufacturing the light-emitting device according to the first embodiment, in the second step, the adhesive layer 130 is cured by applying pressure to the structure 135 while heating the structure 135. Thus, the adhesive strength of the adhesive layer 130 can be improved.

Manufacturing methods according to the second to sixth embodiments are described below with reference to FIGS. 33 to 37. In FIGS. 33 to 37, the position where the slit 121 is formed is indicated by shading. In addition, the position (that is, the dividing line DL) where the structure 135 is divided in the third step is indicated by a two dot chain line.

### Second Embodiment

FIG. 33 is a schematic plan view illustrating a light-transmissive substrate in a method for manufacturing the light-emitting device according to the second embodiment.

The method for manufacturing the light-emitting device according to the second embodiment is substantially the same as the method for manufacturing the light-emitting device according to the first embodiment except that in the first step, a light-transmissive substrate 120A illustrated in FIG. 33 is provided instead of the light-transmissive substrate 120 illustrated in FIG. 30.

As illustrated in FIG. 33, in the method for manufacturing the light-emitting device according to the second embodiment, in the first step, the light-transmissive substrate 120A provided with the slits 121 formed in a matrix form on the second rear surface 120b is provided. The slits 121 include a plurality of first slit regions 121a and a plurality of second slit regions 121b. Each of the plurality of first slit regions 121a extends along the X direction. Each of the plurality of second slit regions 121b extends along the Y direction.

As illustrated in FIG. 33, in the second embodiment, the first slit region 121a is formed at a position overlapping one of two adjacent first dividing lines DL1 and is not formed at a position overlapping the other one of the two adjacent first dividing lines DL1. In the second embodiment, the second slit regions 121b are formed at all positions overlapping the second dividing lines DL2. That is, in the second embodiment, a part of the slit 121 remains on three sides among the four sides of the divided light-transmissive member 20. Thus, as illustrated in FIGS. 9 and 10, the light-emitting device 100A, in which the first regions 23a extend along three sides among the four sides (that is, the first side 20a to the fourth side 20d) of the outer shape (that is, a quadrangle) of the light-transmissive member 20 in top view, can be manufactured.

### Third Embodiment

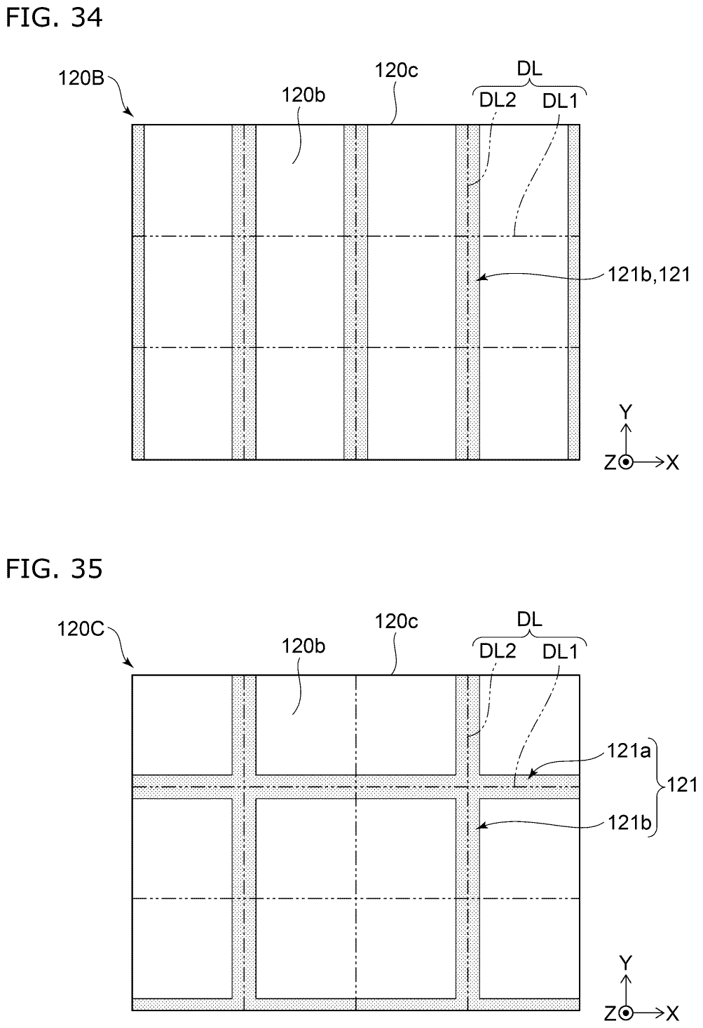

FIG. 34 is a schematic plan view illustrating a light-transmissive substrate in a method for manufacturing the light-emitting device according to the third embodiment.

The method for manufacturing the light-emitting device according to the third embodiment is substantially the same as the method for manufacturing the light-emitting device according to the first embodiment except that in the first step, a light-transmissive substrate 120B illustrated in FIG. 34 is provided instead of the light-transmissive substrate 120 illustrated in FIG. 30.

As illustrated in FIG. 34, in the method for manufacturing the light-emitting device according to the third embodiment, in the first step, the light-transmissive substrate 120B provided with the slits 121 formed on the second rear surface 120b in one direction is provided. The slits 121 include a plurality of second slit regions 121b and include no first slit region 121a. Each of the plurality of second slit regions 121b extends along the Y direction.

As illustrated in FIG. 34, in the third embodiment, the first slit region 121a is not formed at a position overlapping the first dividing line DL1. In the third embodiment, the second slit regions 121b are formed at all positions overlapping the second dividing lines DL2. That is, in the third embodiment, part of the slits 121 remains on two sides facing each other among the four sides of the light-transmissive member 20 obtained by division. Thus, as illustrated in FIGS. 11 and 12, the light-emitting device 100B, in which the first regions 23a extend along two sides facing each other among the four sides (that is, the first side 20a to the fourth side 20d) of the outer shape (that is, a quadrangle) of the light-transmissive member 20 in top view, can be manufactured.

### Fourth Embodiment

FIG. 35 is a schematic plan view illustrating a light-transmissive substrate in a method for manufacturing the light-emitting device according to the fourth embodiment.

The method for manufacturing the light-emitting device according to the fourth embodiment is substantially the same as the method for manufacturing the light-emitting device according to the first embodiment except that in the first step, a light-transmissive substrate 120C illustrated in FIG. 35 is provided instead of the light-transmissive substrate 120 illustrated in FIG. 30.

As illustrated in FIG. 35, in the method for manufacturing the light-emitting device according to the fourth embodiment, in the first step, the light-transmissive substrate 120C provided with the slits 121 formed in a matrix form on the second rear surface 120b is provided. The slits 121 include a plurality of first slit regions 121a and a plurality of second slit regions 121b. Each of the plurality of first slit regions 121a extends along the X direction. Each of the plurality of second slit regions 121b extends along the Y direction.

As illustrated in FIG. 35, in the fourth embodiment, the first slit region 121a is formed at a position overlapping one of two adjacent first dividing lines DL1 and is not formed at a position overlapping the other one of the two adjacent first dividing lines DL1. In the fourth embodiment, the second slit region 121b is formed at a position overlapping one of two adjacent second dividing lines DL2 and is not formed at a position overlapping the other one of the two adjacent second dividing lines DL2. That is, in the fourth embodiment, part of the slits 121 remains on two sides adjacent to each other among the four sides of the light-transmissive member 20 obtained by division. Thus, as illustrated in FIGS. 13 and 14, the light-emitting device 100C, in which the first regions 23a extend along two sides adjacent to each other among the four sides (that is, the first side 20a to the fourth side 20d) of the outer shape (that is, a quadrangle) of the light-transmissive member 20 in top view, can be manufactured.

### Fifth Embodiment

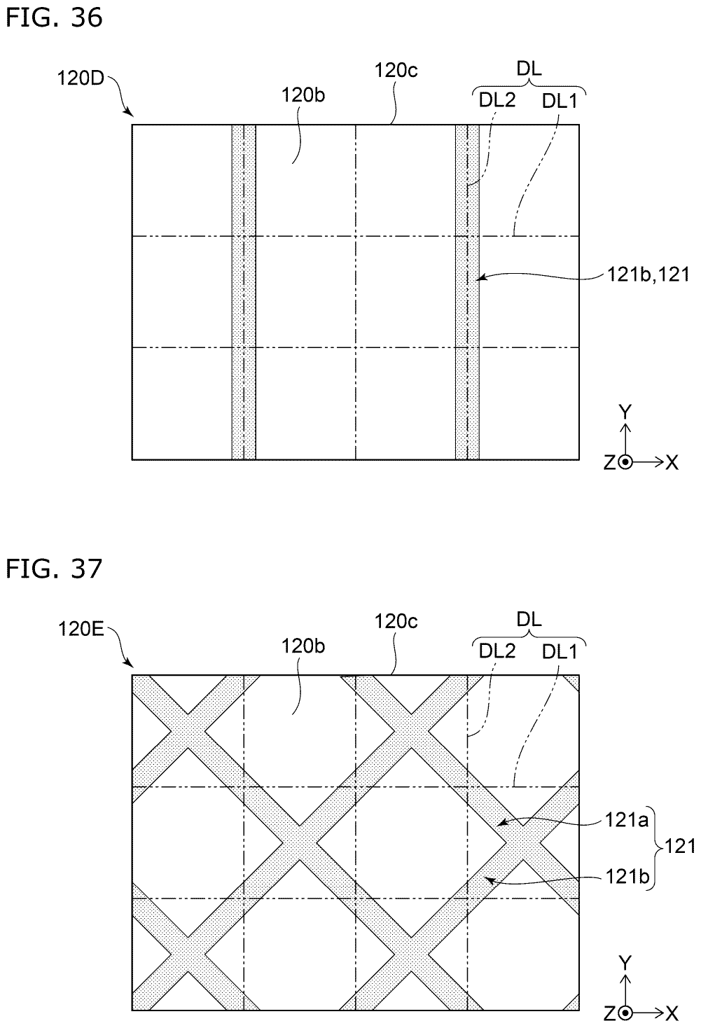

FIG. 36 is a schematic plan view illustrating a light-transmissive substrate in a method for manufacturing the light-emitting device according to the fifth embodiment.

The method for manufacturing the light-emitting device according to the fifth embodiment is substantially the same as the method for manufacturing the light-emitting device according to the first embodiment except that in the first step, a light-transmissive substrate 120D illustrated in FIG. 36 is provided instead of the light-transmissive substrate 120 illustrated in FIG. 30.

As illustrated in FIG. 36, in the method for manufacturing the light-emitting device according to the fifth embodiment, in the first step, the light-transmissive substrate 120D provided with the slits 121 formed on the second rear surface 120b in one direction is provided. The slits 121 include a plurality of second slit regions 121b and include no first slit region 121a. Each of the plurality of second slit regions 121b extends along the Y direction.

As illustrated in FIG. 36, in the fifth embodiment, the first slit region 121a is not formed at a position overlapping the first dividing line DL1. In the fifth embodiment, the second slit region 121b is formed at a position overlapping one of two adjacent second dividing lines DL2 and is not formed at a position overlapping the other one of the two adjacent second dividing lines DL2. That is, in the fifth embodiment, part of the slits 121 remains on one of the four sides of the light-transmissive member 20 obtained by division. Thus, as illustrated in FIGS. 15 and 16, the light-emitting device 100D, in which the first region 23a extends along one side among the four sides (that is, the first side 20a to the fourth side 20d) of the outer shape (that is, a quadrangle) of the light-transmissive member 20 in top view, can be manufactured.

### Sixth Embodiment

FIG. 37 is a schematic plan view illustrating a light-transmissive substrate in a method for manufacturing the light-emitting device according to the sixth embodiment.

The method for manufacturing the light-emitting device according to the sixth embodiment is substantially the same as the method for manufacturing the light-emitting device according to the first embodiment except that in the first step, a light-transmissive substrate 120E illustrated in FIG. 37 is provided instead of the light-transmissive substrate 120 illustrated in FIG. 30.

As illustrated in FIG. 37, in the method for manufacturing the light-emitting device according to the sixth embodiment, in the first step, the light-transmissive substrate 120E provided with the slits 121 formed in a matrix form on the second rear surface 120b is provided. The slits 121 include a plurality of first slit regions 121a and a plurality of second slit regions 121b. Each of the plurality of first slit regions 121a extends along a direction intersecting the X direction and the Y direction. Each of the plurality of second slit regions 121b extends along a direction intersecting the X direction, the Y direction, and the direction in which the plurality of first slit regions 121a extend. The direction in which the plurality of second slit regions 121b extend is orthogonal to the direction in which the plurality of first slit regions 121a extend.

As illustrated in FIG. 37, in the sixth embodiment, the first slit region 121a and the second slit region 121b overlap the intersections of the first dividing line DL1 and the second dividing line DL2. Thus, as illustrated in FIGS. 17 and 18, the light-emitting device 100E, in which the first region 23a is disposed at each of the four corners of the outer shape (that is, a quadrangle) of the light-transmissive member 20 in top view, can be manufactured.

Also in the method for manufacturing the light-emitting device according to each of the second to sixth embodiments, the light-transmissive substrate 120 provided with the slits 121 formed on the second rear surface 120b is provided in the first step and the structure 135 is divided such that part (that is, the inclined surface 121s) of the slits 121 remain in the light-transmissive substrate 120 (that is, the light-transmissive member 20) after the singulation in the third step, thereby easily manufacturing the light-emitting device including the first region 23a formed in the second lateral surface 23 of the light-transmissive member 20. Thus, the light-emitting device with enhanced luminance can be easily manufactured.

As described above, the embodiments can provide light-emitting devices that can enhance luminance and methods for manufacturing the light-emitting devices.

Each of the aforementioned embodiments is an example embodying the present invention, and the present invention is not limited to these embodiments. For example, additions, deletions, or changes of some components or steps in each of the aforementioned embodiments are also included in the present invention. The aforementioned embodiments can be implemented in combination with each other.

What is claimed is:

1. A light-emitting device comprising:
a light-emitting element; and
a light-transmissive member disposed on the light-emitting element, wherein:
the light-emitting element has a first upper surface, a first lower surface, and at least one first lateral surface connecting the first upper surface and the first lower surface,
the light-transmissive member has a second upper surface, a second lower surface, and at least one second lateral surface connecting the second upper surface and the second lower surface,
the at least one second lateral surface comprises a first region inclined toward a center of the second lower surface as the first region extends downward,
the first region is a flat surface or a curved surface,
in a top view, an outer peripheral end of each of the at least one second lateral surface overlaps an outer peripheral end of each of the at least one first lateral surface, and
in the top view, an outer peripheral end of the second lower surface overlaps a lower end of the first region.

2. The light-emitting device according to claim 1, wherein:
each of the at least one second lateral surface further comprises a second region located above the first region, and
the second region is a surface connected to the first region and extending along an up-down direction.

3. The light-emitting device according to claim 1, wherein the first region is a curved surface.

4. The light-emitting device according to claim 2, wherein the first region is a curved surface.

5. The light-emitting device according to claim 1, wherein:
the at least one second lateral surface comprises a plurality of second lateral surfaces,
in the top view, an outer shape of the light-transmissive member is a quadrangle, and the first regions of the plurality of second lateral surfaces extend along two opposite sides of four sides of the quadrangle.

6. The light-emitting device according to claim 2, wherein:
the at least one second lateral surface comprises a plurality of second lateral surfaces,
in the top view, an outer shape of the light-transmissive member is a quadrangle, and the first regions of the plurality of second lateral surfaces extend along two opposite sides of four sides of the quadrangle.

7. The light-emitting device according to claim 1, wherein:
the at least one second lateral surface comprises a plurality of second lateral surfaces,
in the top view, an outer shape of the light-transmissive member is a quadrangle, and the first regions of the plurality of second lateral surfaces extends along four sides of the quadrangle.

8. The light-emitting device according to claim 2, wherein:
the at least one second lateral surface comprises a plurality of second lateral surfaces,
in the top view, an outer shape of the light-transmissive member is a quadrangle, and the first regions of the plurality of second lateral surfaces extends along four sides of the quadrangle.

9. The light-emitting device according to claim 1, wherein the light-transmissive member contains a phosphor.

10. The light-emitting device according to claim 2, wherein the light-transmissive member contains a phosphor.

11. The light-emitting device according to claim 9, wherein the phosphor contains at least one of an oxide phosphor, a nitride phosphor, and an oxynitride phosphor.

12. The light-emitting device according to claim 1, further comprising:
a light reflecting member surrounding a periphery of the light-emitting element and a periphery of the light-transmissive member, wherein
the light reflecting member is in contact with the at least one first lateral surface and the at least one second lateral surface, and is located between the first upper surface and the first region in an up-down direction.

13. The light-emitting device according to claim 2, further comprising:
a light reflecting member surrounding a periphery of the light-emitting element and a periphery of the light-transmissive member, wherein:
the light reflecting member is in contact with the at least one first lateral surface and the at least one second lateral surface, and is located between the first upper surface and the first region in the up-down direction.

14. A method for manufacturing a light-emitting device, comprising:
providing a wafer comprising a plurality of light-emitting elements and having a first main surface and a first rear surface,
providing a light-transmissive substrate having a second main surface and a second rear surface comprising a slit, the slit having an inclined surface inclined so as to widen from the second main surface toward the second rear surface, the inclined surface being a flat surface or a curved surface;
bonding the second rear surface of the light-transmissive substrate to the first main surface of the wafer to form a structure in which the light-transmissive substrate is bonded to the wafer; and
collectively singulating the wafer and the light-transmissive substrate into individual structures by dividing the structure at a position overlapping the slit, wherein the structure is divided such that a part of the slit remains in the light-transmissive substrate of one of the individual structures.

15. The method according to claim 14, wherein, in the step of providing, the slit is in a matrix form.

16. The method according to claim 14, wherein:
in the step of providing, the slit is connected to a lateral surface connecting the second main surface and the second rear surface, and
in the step of bonding, the second rear surface is bonded to the first main surface via an adhesive layer.

17. The method for manufacturing a light-emitting device according to claim 15, wherein:
in the step of providing, the slit is connected to a lateral surface connecting the second main surface and the second rear surface is provided, and
in the step of bonding, the second rear surface is bonded to the first main surface via an adhesive layer.

18. The method according to claim 14, whereinthe light-transmissive member contains a phosphor.
